(19) United States
(12) Patent Application Publication
(10) Pub. No.: US 2024/0157280 A1
(43) Pub. Date: May 16, 2024

(54) DUST COLLECTION DEVICE AND PLASMA EQUIPMENT

(71) Applicant: CHANGXIN MEMORY TECHNOLOGIES, INC., Hefei City, Anhui (CN)

(72) Inventor: Huaiqing WANG, Hefei City (CN)

(73) Assignee: CHANGXIN MEMORY TECHNOLOGIES, INC., Hefei City, Anhui (CN)

(21) Appl. No.: 17/597,506

(22) PCT Filed: Aug. 12, 2021
(86) PCT No.: PCT/CN2021/112220

§ 371 Date: Jan. 8, 2022

(30) Foreign Application Priority Data
Aug. 4, 2021 (CN) 202110892226.7

(51) Int. Cl. B01D 45/16; H01L 21/67

(52) U.S. Cl. CPC B01D 45/16; H01L 21/67017

(57) ABSTRACT

The present application relates to the technical field of semiconductor manufacturing equipment, and provides a dust collection device. The dust collection device includes: an air inlet channel, a dust settling channel extending along a preset path, an airflow rotation channel surrounding the settling channel, an air outlet channel and a collection chamber, where one end of the airflow rotation channel is communicated with the dust settling channel, and the other end of the airflow rotation channel is communicated with the air outlet channel; an upstream end of the dust settling channel is communicated with the air inlet channel, and a downstream end of the dust settling channel is communicated with the collection chamber; and the height of the dust settling channel gradually decreases in an extension direction of the preset path. Dust in the airflow rotation channel can easily settle under the action of a centrifugal force when moving along the airflow rotation channel, and the other end of the airflow rotation channel is communicated with the air outlet channel to discharge air.

### TECHNICAL FIELD

The present application belongs to the technical field of semiconductor manufacturing equipment, and specifically relates to a dust collection device and plasma equipment.

### BACKGROUND

In modern semiconductor manufacturing, a lot of dust is often generated during production, such as when a semiconductor is processed by plasma equipment. At present, in order to filter the dust, the dust is typically carried in an airflow to pass through a vertical pipe. The side wall of the vertical pipe is connected to a horizontal pipe, which is typically connected to a vacuum pump. The airflow enters the horizontal pipe through the vertical pipe. When the airflow moves along the vertical pipe, a small part of dust is settled on the bottom of the vertical pipe, and a large amount of dust enters the horizontal pipe, which results in low dust filtration efficiency. In addition, the large amount of dust entering the horizontal pipe can easily enter the vacuum pump to damage the vacuum pump.

### SUMMARY OF THE INVENTION

### Technical Problem

An objective of the present application is to provide a dust collection device to solve the technical problem of low dust filtration efficiency in the prior art.

### Technical Solution

In order to achieve the above objective, the present application provides a dust collection device. The dust collection device includes: an air inlet channel, a dust settling channel extending along a preset path, an airflow rotation channel surrounding the settling channel, an air outlet channel and a collection chamber, where an inside end of the airflow rotation channel is communicated with the dust settling channel, and an outside end of the airflow rotation channel is communicated with the air outlet channel; an upstream end of the dust settling channel is communicated with the air inlet channel, and a downstream end of the dust settling channel is communicated with the collection chamber; and the height of the dust settling channel gradually decreases in an extension direction of the preset path.

In an embodiment, a cross section of the dust settling channel on the preset path may gradually narrow.

In an embodiment, an inner surface of the dust settling channel may be a tapered surface.

In an embodiment, an edge of the cross section of the dust settling channel may be an arc, and an unclosed part of the arc may correspond to the inside end of the airflow rotation channel.

In an embodiment, the arc may be concave toward the inside of the dust settling channel.

In an embodiment, the airflow rotation channel may gradually extend to the outside of the dust settling channel in a rolled structure.

In an embodiment, the dust collection device may further include a rolled plate; and the rolled plate may surround the outside of the dust settling channel to form the airflow rotation channel.

In an embodiment, the preset path may extend in a vertical direction.

In an embodiment, a longitudinal section of the airflow rotation channel along the preset path may be defined by multiple straight air gaps having a preset width and arranged obliquely with respect to the vertical direction.

In an embodiment, a lower end of each of the air gaps may be close to the dust settling channel, and an upper end of each of the air gaps may be away from the dust settling channel.

In an embodiment, the lower end of each of the air gaps may be communicated with the collection chamber.

In an embodiment, the dust collection device may further include an airflow guide channel; one end of the airflow guide channel may be communicated with a discharge channel, and the other end of the airflow guide channel may be communicated with the airflow rotation channel; and an angle between an airflow direction in the airflow guide channel and that at an outlet of the airflow rotation channel may be greater than zero.

In an embodiment, the dust collection device may further include a box body with an accommodating chamber; the accommodating chamber may be located directly below the collection chamber; and a valve may be provided between the collection chamber and the accommodating chamber.

In an embodiment, the dust collection device may further include an observation mirror for observing a dust accumulation state in the collection chamber.

In an embodiment, the dust collection device may further include a jet port for jetting nitrogen into an inlet of the dust settling channel.

The present application further provides a plasma equipment. The plasma equipment includes a process chamber, a vacuum pump and the above-mentioned dust collection device, where the process chamber is communicated with the air inlet channel, and the air outlet channel is communicated with the vacuum pump.

### Beneficial Effects

The dust collection device provided by the present application has the following beneficial effects. Compared with the prior art, in the dust collection device provided by the present application, the airflow carrying dust enters the dust settling channel from the air inlet channel. The dust settling channel extends along a preset path, and the height of the dust settling channel gradually decreases in the extension direction of the preset path, such that the dust gradually descends and settles while moving along the dust settling channel. The downstream end of the dust settling channel is communicated with the collection chamber, and the dust settled at the downstream end of the dust settling channel can be stored in the collection chamber. The airflow rotation channel surrounds the dust settling channel, and one end of the airflow rotation channel is communicated with the dust settling channel, such that the dust in the airflow rotation channel can easily settle under the action of a centrifugal force when moving along the airflow rotation channel. The other end of the airflow rotation channel is communicated with the air outlet channel to discharge air.

### BRIEF DESCRIPTION OF THE DRAWINGS

To describe the technical solutions in the embodiments of the present application more clearly, the drawings required for describing the embodiments or the prior art are described briefly below. Apparently, the drawings in the following description merely show some embodiments of the present application, and those of ordinary skill in the art may still derive other drawings from these drawings without creative efforts.

FIG. 1 is a stereoscopic view of a dust collection device according to an embodiment of the present application;

FIG. 2 is a front view of the dust collection device according to an embodiment of the present application;

FIG. 3 is a top view of the dust collection device according to an embodiment of the present application;

FIG. 4 is a sectional view along A-A in FIG. 3;

FIG. 5 is a sectional view illustrating rolling of a rolled plate according to an embodiment of the present application;

FIG. 6 is a stereoscopic view illustrating the rolling of the rolled plate according to an embodiment of the present application;

FIG. 7 is a view illustrating a deflector according to an embodiment of the present application;

FIG. 8 is a top view of a first annular baffle according to an embodiment of the present application;

FIG. 9 is a top view of a second annular baffle according to an embodiment of the present application;

FIG. 10 is a top view of a rolled body according to an embodiment of the present application; and

FIG. 11 is a bottom view of the rolled body according to an embodiment of the present application.

### DETAILED DESCRIPTION

Implementations of the Disclosure

To make the to-be-resolved technical problems, technical solutions and beneficial effects of the present application clearer, the present application is described in further detail below with reference to the drawings and embodiments. It should be understood that the specific embodiments described herein are merely intended to explain the present application, rather than to limit the present application.

It should be noted that when a component is “fixed” or “provided” on the other component, the component may be “fixed” or “provided” on the other component directly or indirectly. When a component is “connected” to the other component, the component may be “connected” to the other component directly or indirectly.

It should be noted that, in the description of the embodiments of the present application, unless otherwise specified, “I” means “or”, for example, “A/B” may mean “A or B”. The term “and/or” herein merely describes associations between associated objects, and it indicates three types of relationships. For example, “A and/or B” may indicate that “A exists alone”, “A and B coexist” and “B exists alone”. “A” and “B” may be singular or plural, respectively.

It should be understood that, the terms such as “length”, “width”, “upper”, “lower”, “front”, “rear”, “left”, “right”, “vertical”, “horizontal”, “top”, “bottom”, “inside” and “outside” indicate the orientation or position relationships based the drawings. They are merely intended to facilitate and simplify the description of the present application, rather than to indicate or imply that the mentioned device or component must have a specific orientation or must be constructed and operated in a specific orientation. Therefore, these terms should not be construed as a limitation to the present application.

Moreover, the terms such as “first” and “second” are used only for the purpose of description and should not be construed as indicating or implying a relative importance, or implicitly indicating a quantity of indicated technical features. Thus, features defined with “first” and “second” may explicitly or implicitly include one or more of the features. In the description of the present application, “multiple” means two or more, unless otherwise specifically defined.

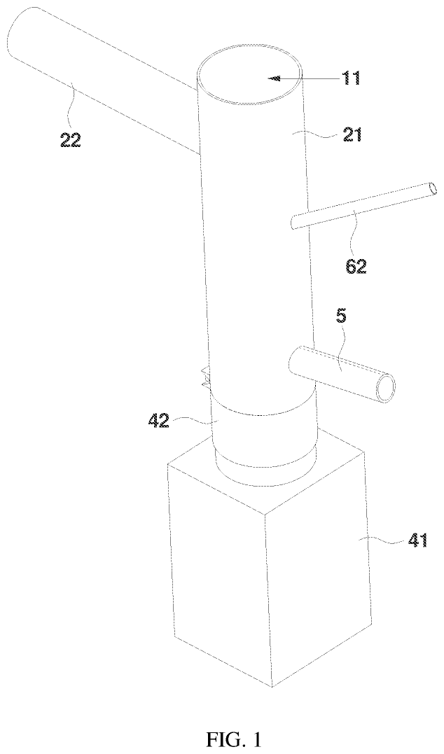

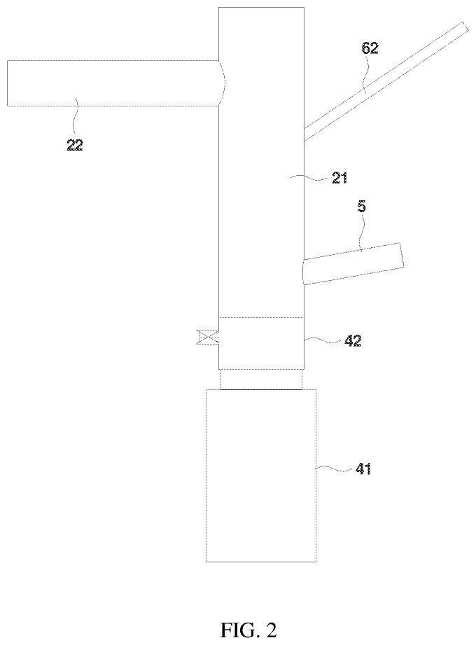

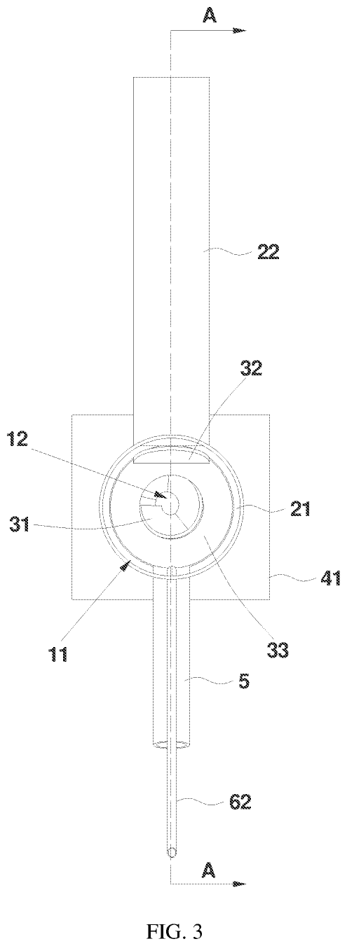

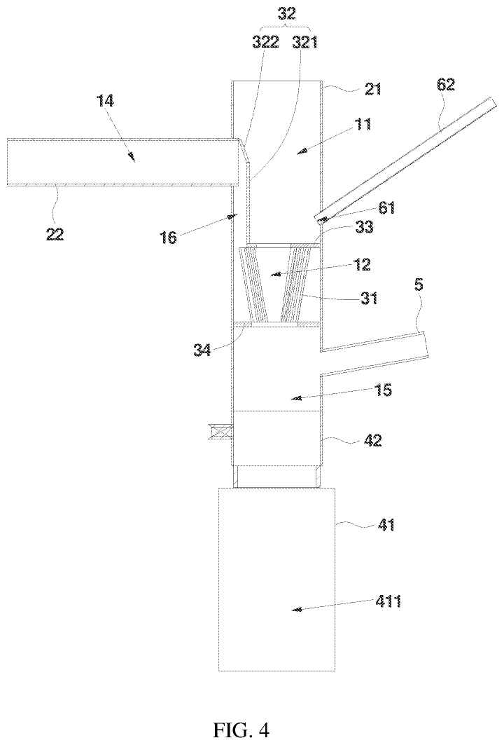

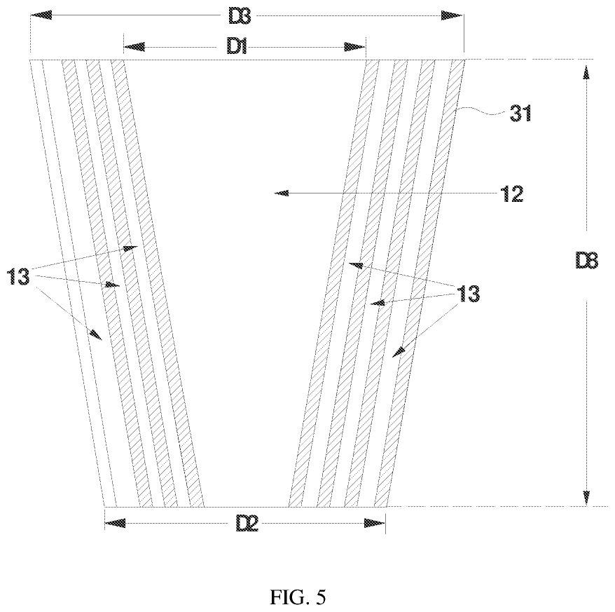

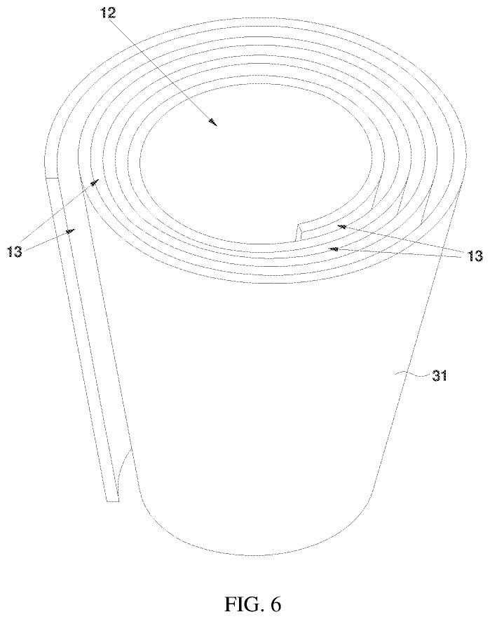

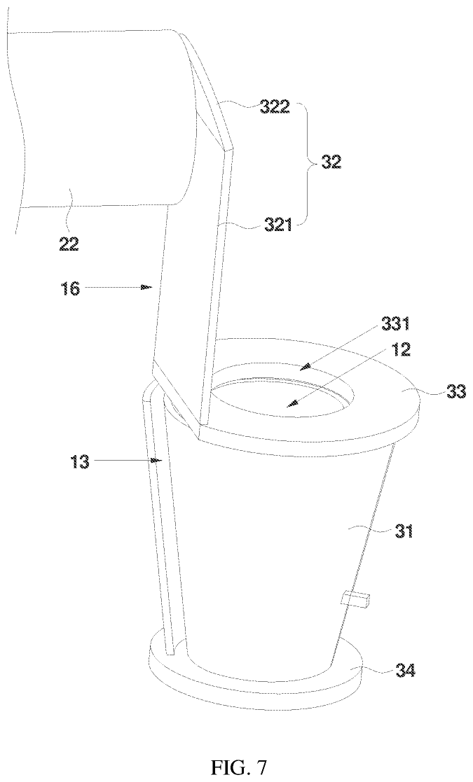

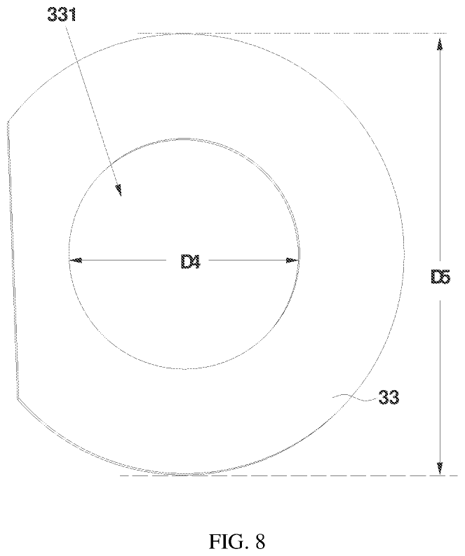

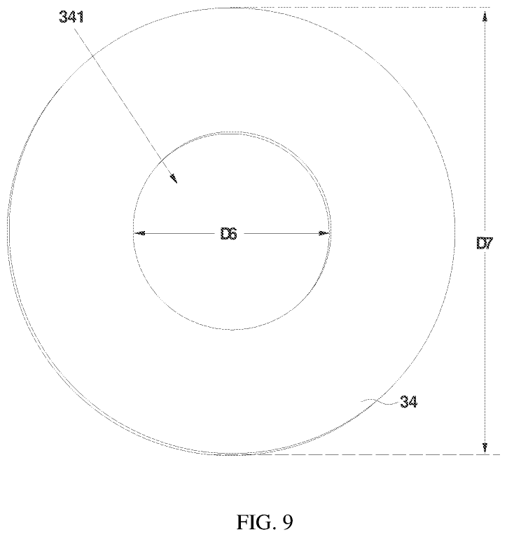

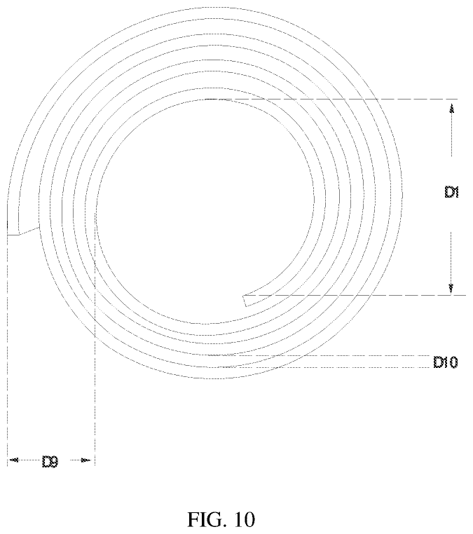

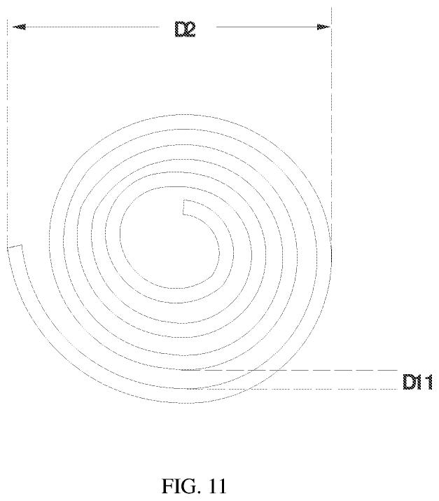

Referring to FIGS. 1 to 11, the present application provides a dust collection device provided. The dust collection device includes: an air inlet channel 11, a dust settling channel 12 extending along a preset path, an airflow rotation channel 13 surrounding the settling channel, an air outlet channel 14 and a collection chamber 15. One end of the airflow rotation channel 13 (for example, an inside end of the airflow rotation channel 13) is communicated with the dust settling channel 12, and the other end of the airflow rotation channel 13 (for example, an outside end of the airflow rotation channel 13) is communicated with the air outlet channel 14. An upstream end of the dust settling channel 12 is communicated with the air inlet channel 11, and a downstream end of the dust settling channel 12 is communicated with the collection chamber 15. The height of the dust settling channel 12 gradually decreases in an extension direction of the preset path.

In this way, the airflow carrying dust enters the dust settling channel 12 from the air inlet channel 11. The dust settling channel 12 extends along a preset path, and the height of the dust settling channel 12 gradually decreases in the extension direction of the preset path, such that the dust gradually descends and settles while moving along the dust settling channel 12. The downstream end of the dust settling channel 12 is communicated with the collection chamber 15, and the dust settled at the downstream end of the dust settling channel 12 can be stored in the collection chamber 15. The airflow rotation channel 13 surrounds the dust settling channel 12, and one end of the airflow rotation channel 13 is communicated with the dust settling channel 12, such that the dust in the airflow rotation channel 13 can easily settle under the action of a centrifugal force when moving along the airflow rotation channel 13. The other end of the airflow rotation channel 13 is communicated with the air outlet channel 14 to discharge air.

In an embodiment, the air inlet channel 11 may be a first pipe 21 or a space for air flow. In an embodiment, the first pipe 21 is a plastic pipe or a metal pipe. In an embodiment, a deflector 32 is located in the first pipe 21. In an embodiment, a rolled plate 31 is located in the first pipe 21. In an embodiment, the air inlet channel 11 is located in the first pipe 21. In an embodiment, a guide channel 16 is located in the first pipe 21. In an embodiment, the collection chamber 15 is located in the first pipe 21.

In an embodiment, the dust settling channel 12 may be a second pipe or a space for air flow. In an embodiment, the second pipe is a plastic pipe or a metal pipe.

In an embodiment, the airflow rotation channel 13 may be a third pipe or a space for air flow. In an embodiment, the third pipe is a plastic pipe or a metal pipe.

In an embodiment, the air outlet channel 14 may be a fourth pipe 22 or a space for air flow. In an embodiment, the fourth pipe 22 is a plastic pipe or a metal pipe.

In an embodiment, the collection chamber 15 may be shaped like a rectangular parallelepiped or a sphere.

Further, referring to FIGS. 1 to 11, as a specific implementation of the dust collection device provided by the present application, a cross section of the dust settling channel 12 on the preset path gradually narrows. In this way, when the airflow moves along the dust settling channel 12, it is convenient for the dust to contact a surface of the dust settling channel 12 and settle.

Further, referring to FIGS. 1 to 11, as a specific implementation of the dust collection device provided by the present application, an inner surface of the dust settling channel 12 is a tapered surface. In this way, when the airflow moves along the dust settling channel 12, the tapered surface can gently guide the airflow to converge, and it is convenient for the dust to contact the tapered surface and settle along the tapered surface.

Further, referring to FIGS. 1 to 11, as a specific implementation of the dust collection device provided by the present application, an edge of the cross section of the dust settling channel 12 is an arc. In this way, it is convenient for the dust to contact the surface of the dust settling channel 12 and slide along the surface of the dust settling channel 12. In an embodiment, an unclosed part of the arc corresponds to the inside end of the airflow rotation channel 13. The inside end of the airflow rotation channel 13 is communicated with the dust settling channel 12, and the edge of the cross section of the dust settling channel 12 is in an unclosed shape at the inside end of the airflow rotation channel 13.

Further, referring to FIGS. 1 to 11, as a specific implementation of the dust collection device provided by the present application, the arc is concave toward the inside of the dust settling channel 12. In this way, the dust is guided to move to the inside of the dust settling channel 12 when the dust slides along the surface of the dust settling channel 12.

Further, referring to FIGS. 1 to 11, as a specific implementation of the dust collection device provided by the present application, the airflow rotation channel 13 gradually extends to the outside of the dust settling channel 12 in a rolled structure. In this way, when the airflow moves along the rolled airflow rotation channel 13, the flow direction of the airflow changes, which facilitates the settling of the dust. In the airflow rotation channel 13, the dust in the airflow is easily in contact with an inner wall of the airflow rotation channel 13 and settles downward under the action of a centrifugal force.

Further, referring to FIGS. 1 to 11, as a specific implementation of the dust collection device provided by the present application, the dust collection device includes a rolled plate 31, and the rolled plate 31 surrounds the dust settling channel in a rolled structure to form the airflow rotation channel 13. In this way, it is convenient to form the airflow rotation channel 13 by curling the rolled plate 31, and the airflow is stable when passing through gaps of the rolled plate 31.

In an embodiment, the dust collection device further includes a first annular baffle 33. The first annular baffle 33 is provided with a first through hole 331 communicating an opening at an upper end of the dust settling channel 12 with the air inlet channel 11. In an embodiment, the diameter of the first through hole 331 is the same as that of the opening at the upper end of the dust settling channel 12.

In an embodiment, the dust collection device further includes a second annular baffle 34. The second annular baffle 34 is provided with a second through hole 341 communicating an opening at a lower end of the dust settling channel 12 with the collection chamber 15. In an embodiment, the outer diameter of the second through hole 341 is the same as that of the bottom of the rolled plate 31.

In an embodiment, the first annular baffle 33 extends in a horizontal direction. In an embodiment, the second annular baffle 34 extends in the horizontal direction.

In an embodiment, the air inlet channel 11 is located in the first pipe 21. In an embodiment, the air outlet channel 14 is located in the fourth pipe 22.

Further, referring to FIGS. 1 to 11, as a specific implementation of dust collection device provided by the present application, the preset path extends in a vertical direction. In this way, when the dust moves along the dust settling channel 12 extending along the preset path, it is convenient for the dust to settle in the vertical direction.

Further, referring to FIGS. 1 to 11, as a specific implementation of dust collection device provided by the present application, a longitudinal section (or a section) of the airflow rotation channel 13 on the preset path is defined by multiple straight air gaps having a preset width and arranged obliquely with respect to the vertical direction. The straight air gaps can reduce air flow resistance. When the airflow moves along the airflow rotation channel 13, since the longitudinal section of the airflow rotation channel 13 is defined by the straight air gaps having a preset width and obliquely arranged on the preset path, it is convenient for the dust in the airflow to settle along the air gaps of the airflow rotation channel 13 under the action of a centrifugal force.

Further, referring to FIGS. 1 to 11, as a specific implementation of the dust collection device provided by the present application, a lower end of each of the air gaps is close to the dust settling channel 12, and an upper end of each of the air gaps is away from the dust settling channel 12. In this way, it is convenient for the dust rotating along the airflow rotation channel 13 to converge to the dust settling channel 12 during the downward settlement process, which is convenient for collection.

Further, referring to FIGS. 1 to 11, as a specific implementation of the dust collection device provided by the present application, the lower end of each of the air gaps is communicated with the collection chamber 15. In this way, the dust that settles downward in the airflow rotation channel 13 can directly enter the collection chamber 15, which is convenient for collection.

Further, referring to FIGS. 1 to 11, as a specific implementation of the dust collection device provided by the present application, the dust collection device further includes an airflow guide channel 16. One end of the airflow guide channel 16 is communicated with a discharge channel, and the other end of the airflow guide channel 16 is communicated with the airflow rotation channel 13. An angle between an airflow direction in the airflow guide channel 16 and that at an outlet of the airflow rotation channel 13 is greater than zero. In this way, the airflow needs to change direction when entering the airflow guide channel 16 from the airflow rotation channel 13, so as to reduce the dust entering the airflow guide channel 16 from the airflow rotation channel 13.

In an embodiment, an airflow direction in the airflow guide channel 16 is perpendicular to that at the outlet of the airflow rotation channel 13.

In an embodiment, the dust collection device further includes a deflector 32. The airflow guide channel 16 is formed between the deflector 32 and an inner wall of the first pipe 21. One end of the airflow guide channel 16 is communicated with the air outlet channel 14, and the other end of the airflow guide channel 16 is communicated with the airflow rotation channel 13. In this way, the airflow from the airflow rotation channel 13 can enter the air outlet channel 14 through the airflow guide channel 16 and be discharged.

In an embodiment, the deflector 32 includes a longitudinal plate 321 and an inclined plate 322 connected in sequence. The longitudinal plate 321 extends in the vertical direction. In an embodiment, the first annular baffle 33 has a notch. An edge of the notch extends along a straight line. A bottom edge of the vertical plate 321 extends along a straight line, and the bottom edge of the vertical plate 321 abuts against the edge of the notch. In an embodiment, a horizontal width of the vertical plate 321 is 160 mm. The horizontal width of the vertical plate 321 is the same as the length of the edge of the notch so as to avoid air leakage between the horizontal bottom edge of the vertical plate 321 and the edge of the notch. In an embodiment, the airflow guide channel 16 extending along the first pipe 21 is formed between the vertical plate 321 and the inner wall of the first pipe 21. In an embodiment, a bottom end of the airflow guide channel 16 is communicated with the notch of the first annular baffle 33. The air coming out of the airflow rotation channel 13 enters the airflow guide channel 16 through a gap between the notch and the inner wall of the first pipe 21, and enters the air outlet channel 14 along the airflow guide channel 16. In an embodiment, the inclined plate 322 faces an inlet of the air outlet channel 14. When the airflow moves along the airflow guide channel 16, since the inclined plate 322 faces the inlet of the air outlet channel 14, it is convenient for the airflow in the airflow guide channel 16 to enter the air outlet channel 14 under the guidance of the inclined plate 322.

In an embodiment, the width of the inclined plate 322 in the horizontal direction is 24 mm. In an embodiment, the width of the vertical plate 321 in the horizontal direction is 24 mm. In an embodiment, the length of the vertical plate 321 in the horizontal direction is 140 mm.

Further, referring to FIGS. 1 to 11, as a specific implementation of the dust collection device provided by the present application, the dust collection device further includes a box body 41 with an accommodating chamber 411. The accommodating chamber 411 is located directly below the collection chamber 15. A valve 42 is provided between the collection chamber 15 and the accommodating chamber 411. In this way, the valve 42 is opened to allow the dust in the collection chamber 15 to be temporarily stored in the accommodating chamber 411, and the valve 42 is closed to prevent the dust in the collection chamber 15 from being temporarily stored in the accommodating chamber 411.

In an embodiment, the valve 42 is a medium-pressure gate valve.

Further, referring to FIGS. 1 to 11, as a specific implementation of the dust collection device provided by the present application, the dust collection device further includes an observation mirror 5 for observing a dust accumulation state in the collection chamber 15. In this way, a user can observe the accumulation of the dust in the collection chamber 15 through the observation mirror 5.

In an embodiment, the observation mirror 5 is a flange provided on the first pipe 21 and having a light-transmitting lens.

Further, referring to FIGS. 1 to 11, as a specific implementation of the dust collection device provided by the present application, the dust collection device further includes a jet port 61 for jetting nitrogen into an inlet of the dust settling channel 12. In this way, nitrogen is jetted into the dust settling channel 12 through the jet port to accelerate the settling of the dust in the dust settling channel 12 and improve the settling effect in the dust settling channel 12.

In an embodiment, the angle between a jetting direction of the jet port 61 and an air inlet direction at the inlet of the dust settling channel 12 is an acute angle, which is convenient for the gas jetted from the jet port 61 to push the dust in the dust settling channel 12 to move.

In an embodiment, the jet port 61 is connected to a jet pipe 62. In an embodiment, the jet pipe 62 is connected to a gas source. In an embodiment, nitrogen is stored in the gas source.

In an embodiment of the present application, when an “inner diameter” and an “outer diameter” are mentioned, if an inner edge of an annular body defines a first annular part and an outer edge of the annular body defines a second annular part, the “inner diameter” may refer to the radius of the first annular part, and the “outer diameter” may refer to the radius of the second annular part. If the inner edge of the annular body defines a first non-annular part (such as a triangle) and the outer edge of the annular body defines a second non-annular part (such as a triangle), the “inner diameter” may refer to the diameter of the largest inscribed circle in the first non-annular part, and the “outer diameter” may refer to the diameter of the smallest circumscribed circle in the second non-annular part.

In an embodiment, the inner diameter of the first pipe 21 is F1. In an embodiment, F1 is 310 mm. In an embodiment, the inner diameter of the fourth pipe 22 is F2. In an embodiment, F2 is 160 mm. In an embodiment, an innermost side wall of the rolled plate 31 surrounds the dust settling channel 12.

In an embodiment, the rolled plate 31 forms a rolled body along a horizontal annular path.

In an embodiment, a top end surface of the rolled body is horizontal. In an embodiment, a bottom end surface of the rolled body is horizontal. In an embodiment, the top end surface of the rolled plate 31 defines a first rolled belt. In an embodiment, gaps formed between rolled parts of the first rolled belt define the above-mentioned air gaps. In an embodiment, the bottom end surface of the rolled plate 31 defines a second rolled belt. In an embodiment, gaps formed between rolled parts of the second rolled belt define the above-mentioned air gaps. In an embodiment, the inlet of the dust settling channel 12 is annular, and the inner diameter of the inlet of the dust settling channel 12 is D1. In an embodiment, an innermost side wall of the first rolled belt surrounds the inlet of the dust settling channel 12. In an embodiment, the outer diameter of an outermost side wall of the second rolled belt is D2. In an embodiment, the height between top and bottom ends of the rolled plate is D8. In an embodiment, the distance between innermost and outermost side walls of the first rolled belt is D9. In an embodiment, the distance between the rolled parts of the first rolled belt is D10. In an embodiment, the distance between the rolled parts of the second rolled belt is D11. In an embodiment, an outermost side wall of the first rolled belt is annular and has an outer diameter of D3. In an embodiment, the inner diameter of the first annular baffle 33 is D4, and the outer diameter of the first annular baffle 33 is D5. In an embodiment, the inner diameter of the second annular baffle 34 is D6, and the outer diameter of the second annular baffle 34 is D7. In an embodiment, D1 is 150 mm. In an embodiment, D2 is 210 mm. In an embodiment, D3 is 310 mm. In an embodiment, D4 is 150 mm. In an embodiment, D5 is 310 mm. In an embodiment, D6 is 210 mm. In an embodiment, D7 is 310 mm. In an embodiment, D8 is 1,000 mm. In an embodiment, D9 is 80 mm. In an embodiment, D10 is 20 mm. In an embodiment, D11 is 20 mm.

In an embodiment, the gaps formed between the rolled parts of the first rolled belt are blocked by the first annular baffle 33.

In an embodiment, the gaps formed between the rolled parts of the second rolled belt are respectively communicated with the collection chamber 15 so as to facilitate the dust in the gaps between the rolled parts of the second rolled belt to be settled down into the collection chamber 15. In an embodiment, the gaps formed between the rolled parts of the second rolled belt are respectively located directly above the collection chamber 15.

In an embodiment, the dust collection device further includes a fifth pipe communicated with the first pipe 21. The first pipe 21 and the fifth pipe respectively extend in the vertical direction. In an embodiment, the inner diameter of the fifth pipe is 160 mm. In an embodiment, the total length of the first pipe 21 and the fifth pipe is 1,300 mm.

Referring to FIGS. 1 to 11, the present application further provides a plasma equipment. The plasma equipment includes a process chamber, a vacuum pump and the dust collection device. The process chamber is a chamber for the plasma equipment to react or discharge waste, and it is communicated with the air inlet channel. The air outlet channel is communicated with the vacuum pump. In this way, the vacuum pump evacuates the dust collection device through the air outlet channel of the dust collection device, and dust generated in the process chamber enters the dust collection device along with an airflow through the air inlet channel. In the dust collection device, the airflow carrying dust enters the dust settling channel 12 from the air inlet channel 11. The dust settling channel 12 extends along a preset path, and the height of the dust settling channel 12 gradually decreases in the extension direction of the preset path, such that the dust gradually descends and settles while moving along the dust settling channel 12. The downstream end of the dust settling channel 12 is communicated with the collection chamber 15, and the dust settled at the downstream end of the dust settling channel 12 can be stored in the collection chamber 15. The airflow rotation channel 13 surrounds the dust settling channel 12, and one end of the airflow rotation channel 13 is communicated with the dust settling channel 12, such that the dust in the airflow rotation channel 13 can easily settle under the action of a centrifugal force when moving along the airflow rotation channel 13. The other end of the airflow rotation channel 13 is communicated with the air outlet channel 14 to discharge air.

The above described are merely preferred examples of the present application, and are not intended to limit the present application. Any modification, equivalent substitution and improvement without departing from the spirit and principle of the present application should fall within the protection scope of the present application.

1. A dust collection device, comprising: an air inlet channel, a dust settling channel extending along a preset path, an airflow rotation channel surrounding the settling channel, an air outlet channel and a collection chamber, wherein an inside end of the airflow rotation channel is communicated with the dust settling channel, and an outside end of the airflow rotation channel is communicated with the air outlet channel; an upstream end of the dust settling channel is communicated with the air inlet channel, and a downstream end of the dust settling channel is communicated with the collection chamber; and the height of the dust settling channel gradually decreases in an extension direction of the preset path.

2. The dust collection device according to claim 1, wherein a cross section of the dust settling channel on the preset path gradually narrows.

3. The dust collection device according to claim 2, wherein an inner surface of the dust settling channel is a tapered surface.

4. The dust collection device according to claim 1, wherein an edge of a cross section of the dust settling channel is an arc, and an unclosed part of the arc contacts with the inside end of the airflow rotation channel.

5. The dust collection device according to claim 4, wherein the arc is concave toward the inside of the dust settling channel.

6. The dust collection device according to claim 1, wherein the airflow rotation channel gradually spirally extends to the outside of the dust settling channel in a rolled structure.

7. The dust collection device according to claim 6, wherein the dust collection device further comprises a rolled plate; and the rolled plate surrounds the dust settling channel to form the airflow rotation channel.

8. The dust collection device according to claim 7, wherein the preset path extends in a vertical direction.

9. The dust collection device according to claim 8, wherein a longitudinal section of the airflow rotation channel on the preset path is defined by multiple straight air gaps having a preset width and arranged obliquely with respect to the vertical direction.

10. The dust collection device according to claim 9, wherein a lower end of each of the air gaps is close to the dust settling channel, and an upper end of each of the air gaps is away from the dust settling channel.

11. The dust collection device according to claim 9, wherein a lower end of each of the air gaps is communicated with the collection chamber.

12. The dust collection device according to claim 1, wherein the dust collection device further comprises an airflow guide channel; one end of the airflow guide channel is communicated with a discharge channel, and the other end of the airflow guide channel is communicated with the airflow rotation channel; and an angle between an airflow direction in the airflow guide channel and that at an outlet of the airflow rotation channel is greater than zero.

13. The dust collection device according to claim 1, wherein the dust collection device further comprises a box body with an accommodating chamber; the accommodating chamber is located directly below the collection chamber; and a valve is provided between the collection chamber and the accommodating chamber.

14. The dust collection device according to claim 1, wherein the dust collection device further comprises an observation mirror for observing a dust accumulation state in the collection chamber.

15. The dust collection device according to claim 1, wherein the dust collection device further comprises a jet port for jetting nitrogen into an inlet of the dust settling channel.

16. Plasma equipment, comprising a process chamber, a vacuum pump and the dust collection device according to claim 1, wherein the process chamber is communicated with the air inlet channel, and the air outlet channel is communicated with the vacuum pump.
